(19) United States
(12) Patent Application Publication
(10) Pub. No.: US 2025/0324543 A1
(43) Pub. Date: Oct. 16, 2025

(54) WATER-COOLING RADIATOR FOR GRAPHICS CARD

(71) Applicant: Dongguan Youhao Intelligent Technology Co., Ltd., Dongguan (CN)

(72) Inventor: XIANTAO GENG, Dongguan (CN)

(21) Appl. No.: 18/680,792

(22) Filed: May 31, 2024

(30) Foreign Application Priority Data
Apr. 10, 2024 (CN) 202420734241.8

(51) Int. Cl. H05K 7/20

(52) U.S. Cl. CPC H05K 7/20272; H05K 7/20263; H05K 7/20136

(57) ABSTRACT

Disclosed is a water-cooling radiator for a graphics card, including a fan structure, a water pump, water flow channels, and a water cooling structure; the water cooling structure includes a water storage structure and a cold head, a heat dissipation sheet is disposed on the cold head, the heat dissipation sheet is directly attached to a graphics card motherboard, water tanks on two sides of the water storage structure are communicated with the water flow channels, water flow flows from the water flow channels through the water tanks on one side to an interior of the cold head to cool down the heat dissipation sheet, the water flow then flows out from the water tanks on the other side to enter the water flow channels, and the water pump is fixed on one side end of the water flow channels to provide propulsive force to the water flow.

### CROSS-REFERENCE TO RELATED APPLICATIONS

This application claims priority to Chinese Patent Application No. 202420734241.8, filed on Apr. 10, 2024, which is hereby incorporated by reference in its entirety.

### TECHNICAL FIELD

The present disclosure relates to the technical field of radiators, and particularly relates to a water-cooling radiator for a graphics card.

### BACKGROUND

As an efficient cooling solution, a water-cooling radiator for a graphics card has been widely used in the market at present. The water-cooling radiator in the prior art usually includes a water-cooling head, a water pipe, a water pump, a cold radiator and other components, and heat generated by the graphics card is taken away through water circulation to maintain stable operation of the graphics card.

However, the market is dominated by external water cooling radiators, which have some problems and challenges. First, it involves a complex installation process, which requires disassembly and assembly of a motherboard, and considers preventing a water nozzle from contacting electrical components of the graphics card that could result in a short circuit. In addition, suitable mounting locations for a water pump and a water-cooling structure should be identified, which may require modifications to a computer case. The intricate water pathways occupy an interior of the computer case, which is cumbersome to manage, presenting a significant challenge for an ordinary home user.

In terms of function and usage, the external water-cooling radiator poses some potential problems. For example, the water-cooling radiator has some risks, with water leakage being a primary hazard. Failure or damage of the water pipe or a connecting member, if any, could result in fluid leakage and damage other hardware components. Moreover, many users prepare water coolant by themselves when the water coolant is exhausted, which cannot guarantee the insulating properties of the water coolant, and any leakage could probably burn essential components, such as the motherboard and graphics card. Although most of the existing high-end water-cooling radiators have the low water-level alarm functions to prevent the aforesaid accidents, there still remains potential safety hazards.

Further, maintenance of the external water-cooling radiator is another issue that needs to be considered. The coolant needs to be checked and replaced at regular intervals to keep the system running smoothly. At the same time, components such as the water pump and the water pipe, could become aged or damaged after long-term use, and need to be replaced and repaired in real time.

Therefore, developing an integrated water-cooling radiator for a graphics card is a pressing challenge that needs to be addressed by those skilled in the art.

### SUMMARY

An objective of the present disclosure is to provide a water-cooling radiator for a graphics card, so as to solve the problems mentioned in the background art.

In order to achieve the foregoing objective, the present disclosure adopts the following technical solution:
a water-cooling radiator for a graphics card, including a water pump, water flow channels and a water cooling structure, where:
the water cooling structure is fixed in a middle part of the water flow channels, and the water pump is fixed on one side end of the water flow channels; and
the water cooling structure includes a water storage structure and a cold head, a heat dissipation sheet is disposed on the cold head, the heat dissipation sheet is directly attached to the adapted graphics card motherboard, water tanks are disposed on both side ends of the water storage structure, the water tanks on two sides of the water storage structure are communicated with the water flow channels, water flow flows from the water flow channels through the water tanks on one side to an interior of the cold head to cool down the heat dissipation sheet, the water flow then flows out from the water tanks on the other side to enter the water flow channels, and the water pump is fixed on one side end of the water flow channels to provide propulsive force to the water flow.

Further, the water storage structure includes a water tank frame, the water tank frame is provided with a water inlet cavity and a water outlet cavity, the water inlet cavity is isolated from the water outlet cavity through a partition, and water flow between the water inlet cavity and the water outlet cavity does not directly flow.

Further, the water storage structure includes an upper base, a water inlet cover and a water outlet cover are fixed on an upper end of the upper base, an upper water inlet hole is formed on the water inlet cover, and a water outlet hole is formed on the water outlet cover.

Further, the water storage structure further includes a bottom plate, a lower water inlet hole is formed on the bottom plate, and the upper water inlet hole is communicated with the lower water inlet hole.

Further, heat dissipation grooves are formed on the cold head, and the heat dissipation grooves are a plurality of water flow grooves formed by a plurality of layers of sealed convex pieces.

Further, the cold head is provided with a lower base, the heat dissipation grooves are fixed on the lower base, an inner wall of the lower base surrounds the grooves to form a water outlet groove, and the water outlet groove is correspondingly communicated with the water outlet hole.

Further, a bottom surface of the bottom plate is tightly attached to a top surface of the heat dissipation grooves, such that the water can flow from the lower water outlet hole into the water outlet grooves through the heat dissipation grooves, and finally flows out from the water outlet.

Further, the heat dissipation grooves are fixed on a top of the heat dissipation sheet, and the water flows into grooves of the heat dissipation grooves to be in direct contact with the top surface of the heat dissipation grooves.

Further, the water flow channels are divided into inlet and outlet channels and circulation channels, where one end of the inlet and outlet channels is directly connected to the water storage structure, the other end of the inlet and outlet channels is connected to the water pump, and both ends of the circulation channels are connected to the water pump and the inlet and outlet channels to form a closed loop.

Further, the water flow channels include heat dissipation plates and fixed plates, the heat dissipation plates are tooth-shaped, and a tooth edge of the heat dissipation plates are clamped by the fixed plate for fixation.

Compared with the prior art, the present disclosure has the following beneficial effects:

The present disclosure integrates the water-cooling radiator with the graphics card motherboard, the heat dissipation sheet is in direct contact with the graphics card motherboard, the water pump provides the propulsive force to the water flow, the water flow flows into the water cooling structure through the water flow channels, the water flow channels are provided with the heat dissipation plates for dissipating heat from the water, the heat dissipation plates are tooth-shaped capable of improving the heat dissipation efficiency; the water cooling structure includes the water storage structure and the cold head, the water storage structure is configured as the water inlet cavity and the water outlet cavity to divert the water flow, the water storage structure is communicated with the water flow channels, the water flows from the water storage structure into an inner side of the cold head to dissipate heat from the heat dissipation sheet; and the heat dissipation grooves are fixed on the top of the heat dissipation sheet, the contact area between the heat dissipation sheet and the water is accordingly increased and the heat dissipation efficiency is improved. Since the heat dissipation structure is disposed in various places, a water flow process is lengthened in a small space, the heat dissipation effect is greatly improved, a temperature of the graphics card can be greatly reduced; moreover, the water-cooling radiator has a closed design and integrated with the graphics card motherboard, thereby avoiding the water leakage. The present disclosure features strong heat dissipation, good safety, small space occupation, and the like.

### BRIEF DESCRIPTION OF DRAWINGS

FIG. 1 is an overall structural schematic diagram of a water-cooling radiator for a graphics card according to the present disclosure.

FIG. 2 is an internal structural schematic diagram of a water-cooling radiator for a graphics card according to the present disclosure.

FIG. 3 is an enlarged view of P1 in FIG. 2.

FIG. 4 is an overall sectional view of a water-cooling radiator for a graphics card according to the present disclosure.

FIG. 5 is an appearance view of a water cooling structure of a water-cooling radiator for a graphics card according to the present disclosure.

FIG. 6 is an interview view of a water cooling structure of a water-cooling radiator for a graphics card according to the present disclosure.

FIG. 7 is an internal view of a water cooling main body of a water-cooling radiator for a graphics card according to the present disclosure.

FIG. 8 is an enlarged view of P2 in FIG. 7.

FIG. 9 is a bottom view of a cold head of a water-cooling radiator for a graphics card according to the present disclosure.

FIG. 10 is a schematic diagram for mounting of a cold head of a water-cooling radiator for a graphics card according to the present disclosure.

FIG. 11 is a bottom view of a water flow of a cold head of a water-cooling radiator for a graphics card according to the present disclosure.

FIG. 12 is a top view of a water flow of a cold head of a water-cooling radiator for a graphics card according to the present disclosure.

Reference numerals in the accompanying drawings: 1. outer frame; 2. fan structure; 3. water flow channel; 31. inlet and outlet channel; 32. circulation channel; 33. heat dissipation plate; 34. fixed plate; 4. graphics card motherboard; 5. water pump; 6. water cooling structure; 61. water storage structure; 611. water tank frame; 6111. water outlet cavity; 6112. water inlet cavity; 6113. water tank; 612. upper base; 613. water outlet cover; 614. water inlet cover; 615. water outlet hole; 616. upper water inlet hole; 617. bottom plate; 618. lower water inlet hole; 62. cold head; 621. lower baser; 6211. heat dissipation sheet; 6212. fixing hole; 622. heat dissipation groove; 623. water outlet groove; and 624. supporting base.

### DESCRIPTION OF EMBODIMENTS

The technical solutions in the embodiments of the present disclosure are described below clearly and comprehensively in conjunction with the accompanying drawings in the embodiments of the present disclosure. It is obvious that the embodiments described are merely a part of, not all of, embodiments of the present disclosure. All other embodiments obtained by those of ordinarily skilled in the art based on the embodiments of the present disclosure without making creative efforts fall within the scope of protection of the present disclosure.

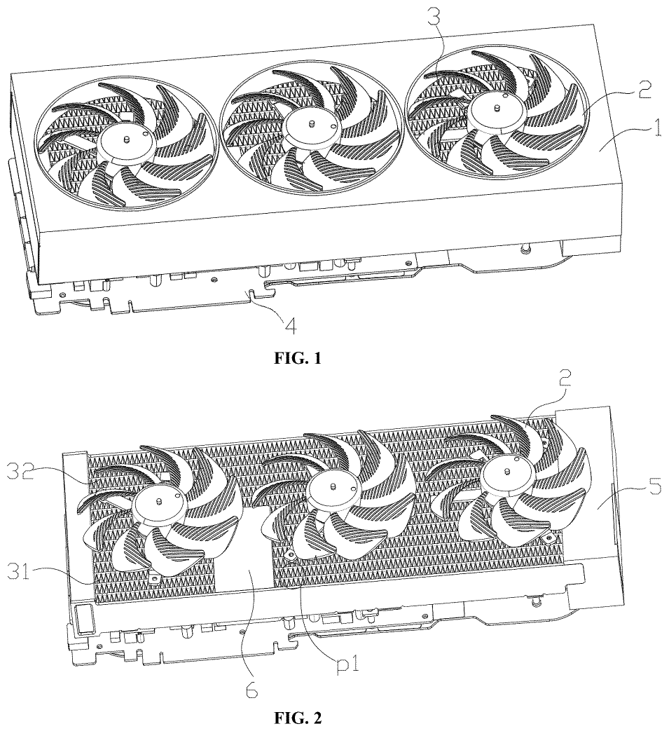

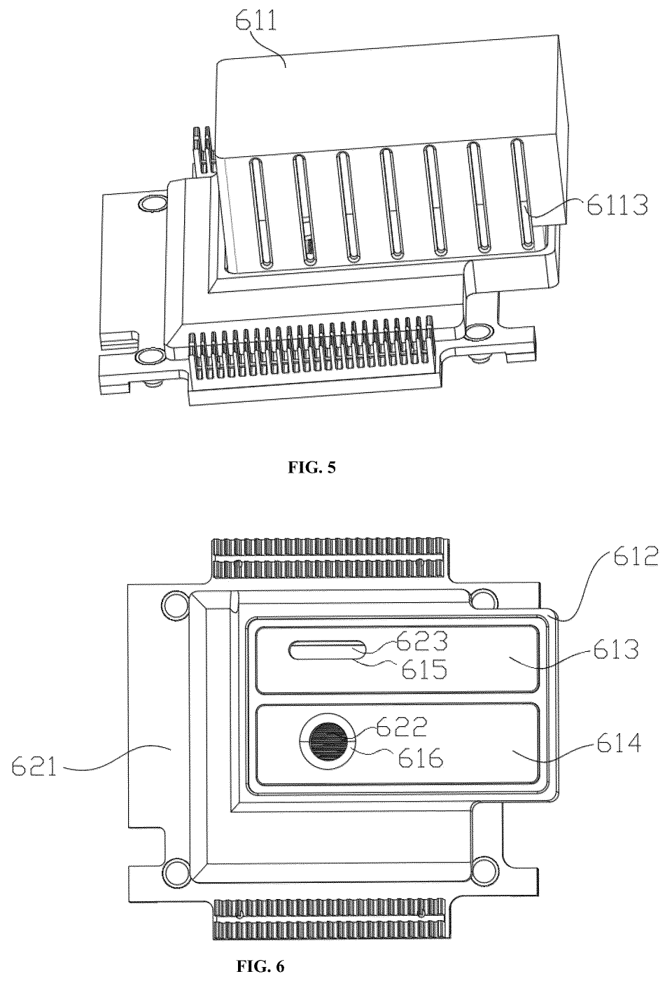

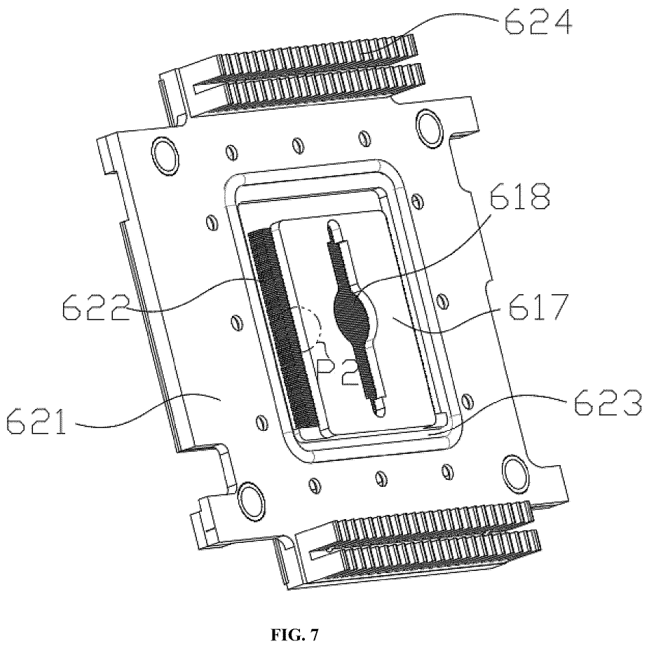

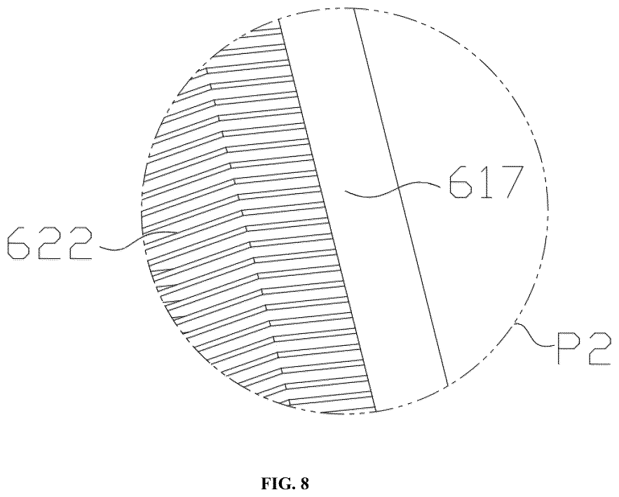

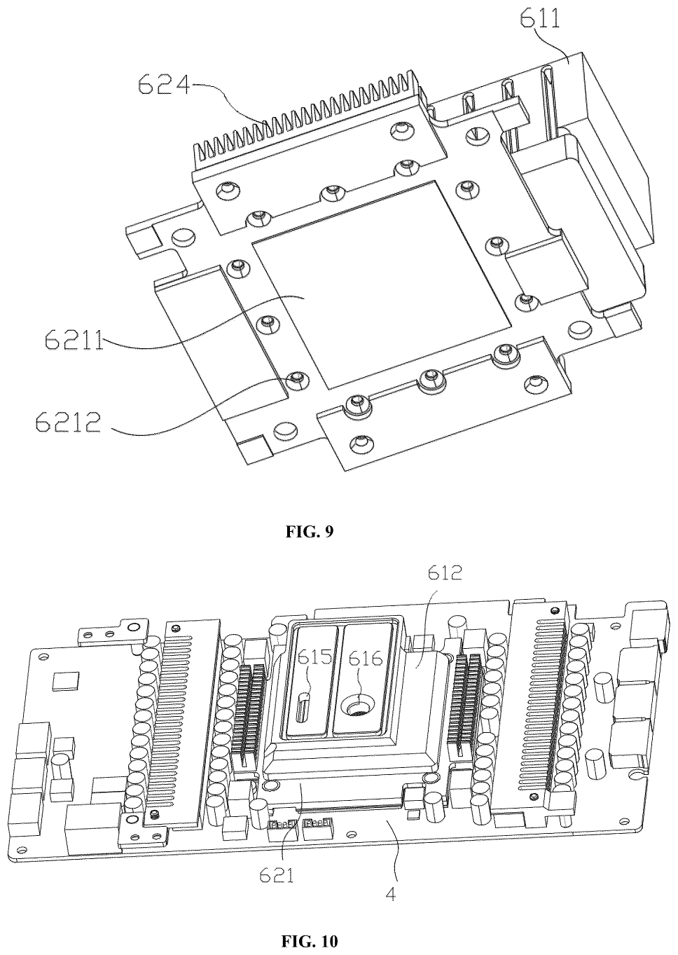

With reference to FIGS. 1-10, a water-cooling radiator for a graphics card is provided, including an outer frame 1, a fan structure 2, a water pump 5, water flow channels 3, and a water cooling structure 6; the water cooling structure 6 is fixed on an upper end of a graphics card motherboard 4, the water cooling structure 6 includes a water storage structure 61 and a cold head 62, a heat dissipation sheet 6211 is disposed on the cold head 62, the heat dissipation sheet 6211 is directly attached to the adapted graphics card motherboard 4, water tanks 6113 are disposed on two sides of the water storage structure 61, the water tanks 6113 on two sides of the water storage structure 61 are communicated with the water flow channels 3, water flow flows from the water flow channels 3 through the water tanks 6113 on one side to an interior of the cold head 62 to cool down the heat dissipation sheet 6211, and the water flow then flows out from the water tanks 6113 on the other side to enter the water flow channels 3; the water pump 5 is fixed on one side end of the water flow channels 3 to provide propulsive force to the water flow, the fan structure is fixed at an upper end of the water flow channels 3, the outer frame 1 is wrapped around the water cooling structure 6 and the graphics card motherboard 4, and the outer frame 1 provides connecting parts for being fixed on a computer host and forms protection of an interior of the outer frame 1; and

Specifically, the water storage structure 61 is provided with a water tank frame 611, the water tanks 6113 are a strip-shaped through holes, which are sequentially disposed on two side surfaces of the water tank frame 611 and are matched with the water flow channels 3, and the water tanks 6113 on two sides are respectively communicated with a water inlet cavity 6112 and a water outlet cavity 6111.

Specifically, the fan structure is preferably three fans, which are uniformly and transversely fixed on an outer side of the water flow channels 3, air inlets corresponds to a side surface of heat dissipation plates 33, and when the fans are turned on, heat dissipation can be performed simultaneously on water and the heat dissipation plates 33 at the same time.

With reference to FIGS. 4-8, the water storage structure 61 includes a water tank frame 611, the water tank frame 611 is provided with the water inlet cavity 6112 and the water outlet cavity 6111, the water inlet cavity 6112 is isolated from the water outlet cavity 6111 through a partition, and water flow between the water inlet cavity 6112 and the water outlet cavity 6111 does not directly flow. The water storage structure 61 includes an upper base 612, a water inlet cover 614 and a water outlet cover 613 are fixed on an upper end of the upper base 612, an upper water inlet hole 616 is formed on the water inlet cover 614, and a water outlet hole 615 is formed on the water outlet cover 613. The water storage structure 61 further includes a bottom plate 617, a lower water inlet hole 618 is formed on the bottom plate 617, and the upper water inlet hole 616 is communicated with the lower water inlet hole 618. Heat dissipation grooves 622 are formed on the cold head 62, and the heat dissipation grooves 622 are a plurality of water flow grooves formed by a plurality of layers of sealed convex pieces. The cold head 62 is provided with a lower base 621, the heat dissipation grooves 622 are fixed on the lower base 621, an inner wall of the lower base 621 surrounds the grooves to form a water outlet groove 623, the water outlet groove 623 is correspondingly communicated with the water outlet hole 615, supporting bases 624 are disposed at two ends of the lower base 621, a top face of the supporting base 624 is in contact with the water flow channels 3 to form stress, and the supporting stability of the water cooling structure 6 is thus improved; and fixing holes 6212 are formed on a bottom face of the lower base 621, and the water cooling structure 6 is fixedly connected to the graphics card motherboard 4 through the fixing holes 6212. A bottom surface of the bottom plate 617 is tightly attached to a top surface of the heat dissipation grooves 622, such that water can only flow from the lower water outlet hole 615 into the water outlet grooves 623 through the heat dissipation grooves 622, and finally flows out from the water outlet. The heat dissipation grooves 622 are fixed on a top of the heat dissipation sheet 6211 to conduct heat for the heat dissipation sheet 6211, such that a contact area between the heat dissipation sheet 6211 and the water is increased, the water flows into grooves of the heat dissipation grooves 622 to be in direct contact with the top surface of the heat dissipation grooves 6211, and the heat dissipation sheet 6211 is cooled down through circulation of water; and
specifically, the upper water inlet hole 616 is a circular opening, and the upper water inlet hole 616 corresponds to the lower water inlet hole 618; in addition to the circular opening corresponding to the upper water inlet hole 616, the lower water inlet hole 618 is provided with elongated through holes on two sides of the circular opening to increase an area of the water inlet hole and improve the water flow efficiency; and the water outlet hole 615 is an elongated through hole, the water outlet hole 615 corresponds to the water outlet groove 623, and the water can flow from the water outlet groove 623 through the water outlet hole 615 into the water outlet cavity 6111.

With reference to FIG. 2, the water flow channels 3 are divided into inlet and outlet channels 31 and circulation channels 32, where one end of the inlet and outlet channels 31 is directly connected to the water storage structure 61, the other end of the inlet and outlet channels 31 is connected to the water pump 5, and both ends of the circulation channels 32 are connected to the water pump 5 and the inlet and outlet channels 31 to form a closed loop.

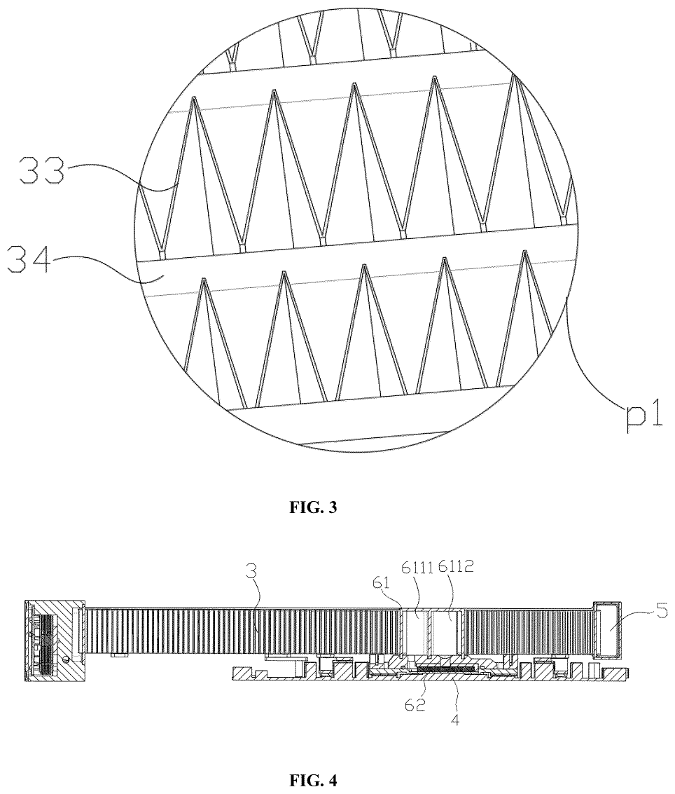

With reference to FIG. 3, the water flow channels 3 include heat dissipation plates 33 and fixed plates 34, the heat dissipation plates 33 are tooth-shaped capable of increasing a flow distance of water, and also increasing a contact area between the heat dissipation plates 33 and the water, such that cooling capacity is improved, and a tooth edge of the heat dissipation plates 33 are clamped by the fixed plate 34 for fixation.

Specific Embodiment 1: both ends of the water pump 5 are connected to the inlet and outlet channels 31 and the circulation channels 32, and the water cooling structure 6 is arranged in a middle of the inlet and outlet channels 31; the water cooling structure 6 includes the water storage structure 61 and the cold head 62, the water storage structure 61 includes the water tank frame 611 and the upper base 612, the water tanks 6113 are disposed on both side ends of the water tank frame 611, the water tanks 6113 on two sides are respectively communicated with the inlet and outlet channels 31, the water tank frame 611 is provided with the water inlet cavity 6112 and the water outlet cavity 6111, and the partition is disposed between the water inlet cavity 6112 and the water outlet cavity 6111 to prevent the direct communication there between; and the upper base 612 is fixed on a lower side of the water tank frame 611, the water inlet cover 614 and the water outlet cover 613 are disposed on an upper surface of the upper base 612 and are respectively matched with peripheral ends of the lower openings of the water inlet cavity 6112 and the water outlet cavity 6111, and the upper water inlet hole 616 and the water outlet hole 615 are formed on the water inlet cover 614 and the water outlet cover 613, respectively.

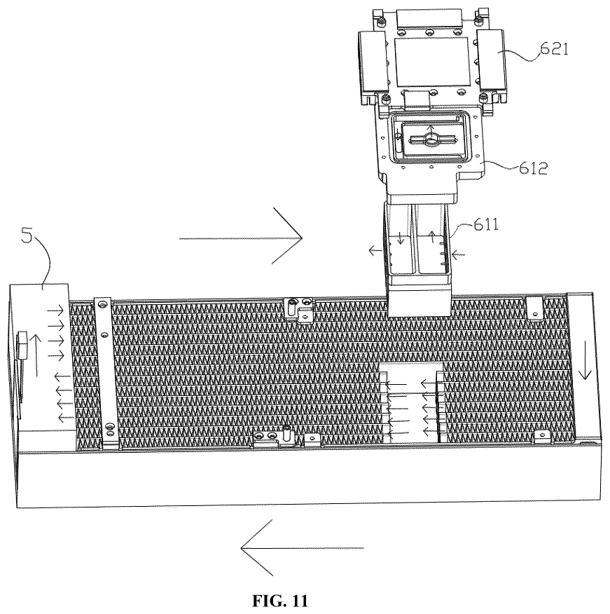

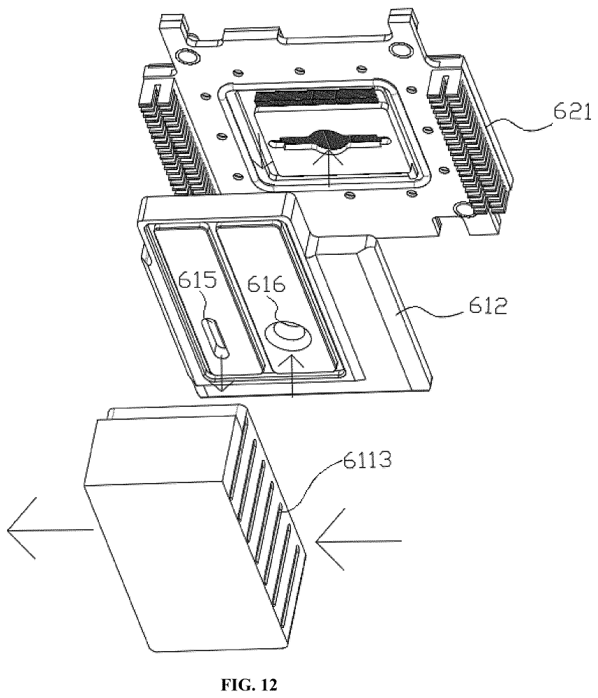

The cold head 62 includes the lower base 621, the lower base 621 is provided with an inner cavity with an upper opening, the inner cavity with the upper opening on the lower base 621 is connected to a lower end of the upper base 612 and a connection thereof is sealed; the heat dissipation grooves 622 are formed in the inner cavity of the lower base 621, the bottom plate 617 is disposed on a bottom of the upper base 612, the heat dissipation grooves 622 are tightly attached to the bottom plate 617, the lower water inlet is formed on the bottom plate 617, the lower water inlet is correspondingly communicated with the upper water inlet, an inner cavity of the lower base 621 is recessed along a cavity wall thereof to form water outlet groove 623, the water outlet is correspondingly communicated with the water outlet groove 623, the heat dissipation sheet 6211 is fixed at a bottom of the heat dissipation grooves 622, and the heat dissipation sheet 6211 is directly attached to the graphics card motherboard 4; and
with reference to FIGS. 11 and 12, water is pushed through the water pump 5 to flow from the water tanks 6113 via the inlet and outlet channels 31 into the water inlet cavity 6112, the water then flows through the upper water inlet hole 616 at a lower end of the water inlet cavity 6112 and the lower water inlet hole 618 on a bottom into the heat dissipation grooves 622, the water then flows through the heat dissipation grooves 622 to both sides to be in full contact with the heat dissipation sheet 6211 and the heat dissipation grooves 622 to cool down the heat dissipation sheet 6211, and finally flows into the water outlet groove 623 and then flows upwards into the water outlet cavity 6111 via the water outlet hole 615 due to the propulsive force of the subsequent water flow, the water then flows into the inlet and outlet channels 31 via the water tanks 6113 on sides of the water outlet cavity 6111, the inlet and outlet channels 31 are communicated with the circulation channels 32, the inlet and outlet channels 31 and the circulation channels 32 are both provided with the heat dissipation plates 33, a terminal of the circulation channels 32 is connected to the water pump 5, the water flows through the heat dissipation plates 33 of the inlet and outlet channels 31 and the circulation channels 32 to cool down and then flows into the water pump 5 to form a closed loop; and a fan is disposed at tops of the inlet and outlet channels 31 and the circulation channels 32 for dissipating heat from the water and the heat dissipation plates 33.

The present disclosure integrates the water-cooling radiator with the graphics card motherboard 4, the heat dissipation sheet 6211 is in direct contact with the graphics card motherboard 4, the water pump 5 provides the propulsive force to the water flow, the water flow flows into the water cooling structure 6 through the water flow channels 3, the water flow channels 3 are provided with the heat dissipation plates 33 for dissipating heat from the water, the heat dissipation plates 33 are tooth-shaped capable of improving the heat dissipation efficiency; the water cooling structure 6 includes the water storage structure 61 and the cold head 62, the water storage structure 61 is configured as the water inlet cavity 6112 and the water outlet cavity 6111 to divert the water flow, the water storage structure 61 is communicated with the water flow channels 3, the water flows from the water storage structure 61 into an inner side of the cold head 62 to dissipate heat from the heat dissipation sheet 6211; and the heat dissipation grooves 622 are fixed on the top of the heat dissipation sheet 6211, the contact area between the heat dissipation sheet 6211 and the water is accordingly increased and the heat dissipation efficiency is improved. Since the heat dissipation structure is disposed in various places, a water flow process is lengthened in a small space, the heat dissipation effect is greatly improved, a temperature of the graphics card can be greatly reduced; moreover, the water-cooling radiator has a closed design and integrated with the graphics card motherboard 4, thereby avoiding the water leakage. The present disclosure features strong heat dissipation, good safety, small space occupation, and the like.

The foregoing descriptions are merely preferred specific implementations of the present disclosure, and are not intended to limit the protection scope of the present disclosure. Any equivalent replacements or changes made by a person skilled in the art according to the technical solution of the present disclosure and the inventive concepts thereof within the technical scope disclosed in the present disclosure shall fall within the protection scope of the present disclosure.

What is claimed is:

1. A water-cooling radiator for a graphics card, comprising a water pump, water flow channels and a water cooling structure, wherein
the water cooling structure is fixed in a middle part of the water flow channels, and the water pump is fixed on one side end of the water flow channels; and
the water cooling structure comprises a water storage structure and a cold head, a heat dissipation sheet is disposed on the cold head, the heat dissipation sheet is directly attached to an adapted graphics card motherboard, water tanks are disposed on both side ends of the water storage structure, the water tanks on two sides of the water storage structure are communicated with the water flow channels, water flow flows from the water flow channels through the water tanks on one side to an interior of the cold head to cool down the heat dissipation sheet, the water flow then flows out from the water tanks on the other side to enter the water flow channels, and the water pump is fixed on one side end of the water flow channels to provide propulsive force to the water flow.

2. The water-cooling radiator for a graphics card according to claim 1, wherein the water storage structure comprises a water tank frame, the water tank frame is provided with a water inlet cavity and a water outlet cavity, the water inlet cavity is isolated from the water outlet cavity through a partition, and water flow between the water inlet cavity and the water outlet cavity does not directly flow.

3. The water-cooling radiator for a graphics card according to claim 2, wherein the water storage structure comprises an upper base, a water inlet cover and a water outlet cover are fixed on an upper end of the upper base, an upper water inlet hole is formed on the water inlet cover, and a water outlet hole is formed on the water outlet cover.

4. The water-cooling radiator for a graphics card according to claim 3, wherein the water storage structure further comprises a bottom plate, a lower water inlet hole is formed on the bottom plate, and the upper water inlet hole is communicated with the lower water inlet hole.

5. The water-cooling radiator for a graphics card according to claim 4, wherein heat dissipation grooves are formed on the cold head, and the heat dissipation grooves are a plurality of water flow grooves formed by a plurality of layers of sealed convex pieces.

6. The water-cooling radiator for a graphics card according to claim 5, wherein the cold head is provided with a lower base, the heat dissipation grooves are fixed on the lower base, an inner wall of the lower base surrounds the grooves to form a water outlet groove, and the water outlet groove is correspondingly communicated with the water outlet hole.

7. The water-cooling radiator for a graphics card according to claim 6, wherein a bottom surface of the bottom plate is tightly attached to a top surface of the heat dissipation grooves, such that the water can flow from the lower water outlet hole into the water outlet grooves through the heat dissipation grooves, and finally flows out from the water outlet.

8. The water-cooling radiator for a graphics card according to claim 7, wherein the heat dissipation grooves are fixed on a top of the heat dissipation sheet, and the water flows into grooves of the heat dissipation grooves to be in direct contact with the top surface of the heat dissipation grooves.

9. The water-cooling radiator for a graphics card according to claim 1, wherein the water flow channels are divided into inlet and outlet channels and circulation channels, one end of the inlet and outlet channels is directly connected to the water storage structure, the other end of the inlet and outlet channels is connected to the water pump, and both ends of the circulation channels are connected to the water pump and the inlet and outlet channels to form a closed loop.

10. The water-cooling radiator for a graphics card according to claim 8, wherein the water flow channels comprise heat dissipation plates and fixed plates, the heat dissipation plates are tooth-shaped, and a tooth edge of the heat dissipation plates are clamped by the fixed plate for fixation.
